(19) United States
(12) Patent Application Publication
(10) Pub. No.: US 2025/0259869 A1
(43) Pub. Date: Aug. 14, 2025

(54) AUTOMATIC BLIND HAND-OFF TO CENTER WAFER REFERRING TO HEATER POCKET

(71) Applicant: Applied Materials, Inc., Santa Clara, CA (US)

(72) Inventors: Yuxing ZHANG, Santa Clara, CA (US); Tuan Anh NGUYEN, San Jose, CA (US); Todd BRILL, Santa Clara, CA (US)

(21) Appl. No.: 19/053,566

(22) Filed: Feb. 14, 2025

Related U.S. Application Data
(60) Provisional application No. 63/553,458, filed on Feb. 14, 2024.

(51) Int. Cl. H01L 21/67; B25J 9/16; B25J 11/00

(52) U.S. Cl. CPC H01L 21/67259; B25J 9/1669; B25J 11/0095

(57) ABSTRACT

Methods and devices for automatically adjusting the position of substrates are provided herein. Embodiments include using a substrate positioning apparatus to adjust a position of a substrate inside a chamber, wherein the adjusting comprises moving the substrate a specified distance in a specified direction. Embodiments further include receiving, from one or more measurement devices, a measured position of the substrate. Embodiments further include calculating a variance between the measured position of the substrate and an expected position of the substrate based on adjustments to the position of the substrate. Embodiments further include detecting that the substrate has reached an edge of a pocket inside the chamber based on the variance exceeding a threshold. Embodiments further include determining, based on the detecting, a configuration for the positioning apparatus that causes the positioning apparatus to place the substrate in a central point of the pocket.

### RELATED APPLICATIONS

This application claims the benefit of U.S. Provisional Application No. 63/553,458, entitled “AUTOMATIC BLIND HAND-OFF TO CENTER WAFER REFERRING TO HEATER POCKET,” by the same inventors, filed 14 Feb. 2024, the contents of which are incorporated herein in their entirety.

### BACKGROUND

### Field

Embodiments of the present disclosure generally relate to devices and methods of processing substrates such as silicon wafers, and more particularly, to automatically positioning a substrate inside a chamber.

### Description of the Related Art

Substrate processing in electronic device fabrication often requires heating the substrate inside a heated chamber. In the heating process, substrates (e.g., disk-shaped substrates) are placed inside chambers that fit closely to the substrate. However, if the substrate is too close to an edge of the heating chamber or an edge of a support for the substrate, the resulting processed substrate may not be processes for optimal performance. Manually placing a substrate inside a chamber and ensuring that the substrate does not hit an edge of the chamber is extremely difficult, as there is very little space between the substrate and the chamber. Corrections to the position of the substrate often amount to less than one millimeter of movement. Overcorrections can result in the substrate hitting another edge of the chamber, which can cause the substrate to shift in an unpredictable manner. Also, even when substrates are correctly placed inside a chamber, the substrates can shift over time and may thus require further adjustments to position during processing.

Accordingly, there is a need in the art for devices and methods for automatically positioning a substrate inside a chamber.

### SUMMARY

Embodiments described herein generally relate to processing substrates such as silicon wafers, and more particularly, to automatically positioning a substrate inside a chamber.

In one embodiment, a method comprises using a substrate positioning apparatus to adjust a position of a substrate inside a chamber, wherein the adjusting comprises moving the substrate a specified distance in a specified direction; receiving, from one or more measurement devices, a measured position of the substrate; calculating a variance between the measured position of the substrate and an expected position of the substrate based on adjustments to the position of the substrate; detecting that the substrate has reached an edge of a pocket within the chamber based on the variance exceeding a threshold; and determining, based on the detecting, a configuration for the positioning apparatus that causes the positioning apparatus to place the substrate in a central point of the pocket within the chamber.

In another embodiment, a method comprises using a substrate positioning apparatus to adjust a position of a substrate inside a chamber, wherein the adjusting comprises moving the substrate a specified distance in a specified direction; receiving, from one or more measurement devices, a first measured position of the substrate; calculating a first variance between the first measured position of the substrate and a first expected position of the substrate, wherein the first expected position is based on adjustments to the position of the substrate; detecting that the substrate has reached a first edge of a pocket within the chamber based on the first variance exceeding a threshold; using the substrate positioning apparatus to move the substrate a specified distance in a direction that is opposite to the specified direction; receiving, from the one or more measurement devices, a second measured position of the substrate; calculating a second variance between the second measured position of the substrate and a second expected position of the substrate, wherein the second expected position is based on the first measured position of the substrate and adjustments to the position of the substrate; detecting that the substrate has reached a second edge of the pocket based on the second variance exceeding a threshold; and determining a configuration for the positioning apparatus by selecting a given configuration for the positioning apparatus that is intermediate to a first configuration of the positioning apparatus that caused the substrate to reach the first edge and a second configuration of the positioning apparatus that caused the substrate to reach the second edge.

In another embodiment, a processing device comprises a processing chamber for receiving a substrate; one or more measurement devices for measuring a position of the substrate; a substrate positioning apparatus that is capable of adjusting the position of the substrate; and a computing device capable of: receiving data from the one or more measurement devices; determining, based on the data received from the measurement devices, the position of the substrate; determining, based on adjustments to the position of the substrate, an expected position of the substrate; calculating a variance between the position of the substrate determined from the data received from the measurement devices and the expected position of the substrate; and determining a configuration for the positioning apparatus based on the calculated variance.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 depicts an example substrate processing system for handling substrates, according to certain embodiments.

FIG. 2 depicts example positioning apparatuses for adjusting the position of a substrate, according to certain embodiments.

FIG. 3 depicts example views of substrates inside chambers, according to certain embodiments.

FIG. 4 is a flow diagram of example operations for automatically positioning a substrate inside a chamber, according to certain embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments described herein generally relate to processing substrates, such as silicon wafers, and more particularly, to automatically positioning a substrate inside a chamber. More particularly, embodiments described herein provide devices and methods for automatically positioning substrates.

Embodiments described herein enable precise and accurate automatic positioning of substrates inside of chambers, in contrast to conventional approaches of manually adjusting substrates to ensure a proper fit. This automatic positioning allows for adjustments to be made during the processing of the substrates, ensuring higher quality processed substrates and increased throughput.

Embodiments described herein incorporate sensors designed to detect the position of a substrate. This detected position is compared to an expected position as a series of incremental adjustments are made to the position of the substrate. A variance (e.g., beyond a threshold) between the detected position and the expected position may indicate that the substrate has hit an edge of a pocket within the chamber that is used for holding the wafer inside the chamber. When it is determined that the substrate has hit an edge of the pocket within the chamber, a limit may be established for the positioning system indicating that the position of the substrate should not be adjusted further in the direction of the edge. The position of the substrate may be adjusted in a direction opposite of the detected edge until a second edge is detected. A second limit may then be established. Based on the first and second limits, a configuration may be selected for the positioning system that causes the positioning system to place the substrate in a position that is located in the center of a line between the first and second edge. This process may be repeated for one or more other directions and corresponding opposite directions to ensure that the substrate is placed in the center of the pocket.

### Example Substrate Processing System

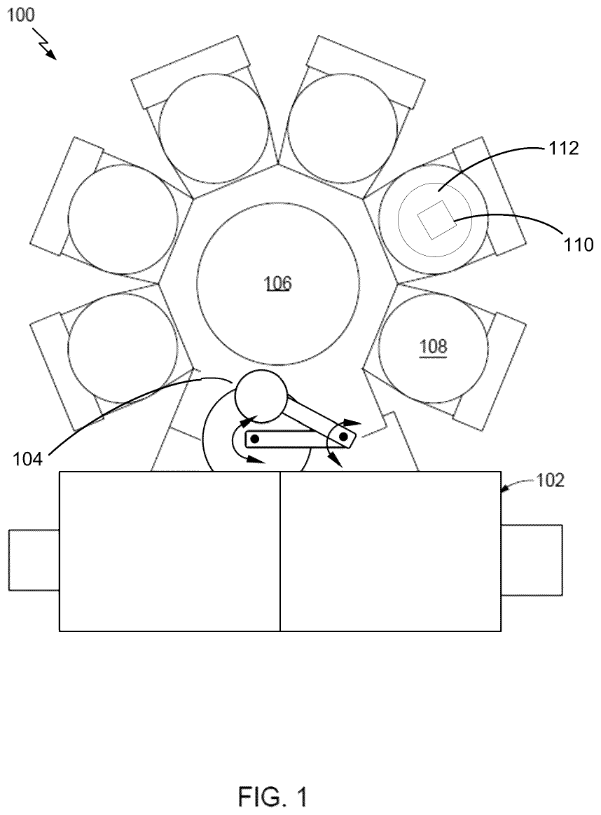

FIG. 1 illustrates an example substrate processing system 100, according to certain embodiments. In certain embodiments, the substrate processing system 100 is particularly configured for processing substrates, such as substrate 112, which may be a circular substrate. While reference may be made herein to circular substrates, it is contemplated that substrates of other geometric shapes may benefit from aspects of the present disclosure. A substrate can be used in the formation of integrated circuits. Substrates may comprise semiconductors such as silicon, germanium, sapphire, or other materials.

Substrate processing system 100 may include substrate positioning apparatus 104, equipment front-end module 102, chamber housing 106, and one or more chambers 108. In some embodiments, each of the chambers includes one or more sensors for measuring the position of a substrate 112. The chambers 108 may be used to heat substrates 112, or to perform other processes on the substrate 112, such as deposition, etching, cleaning, and the like.

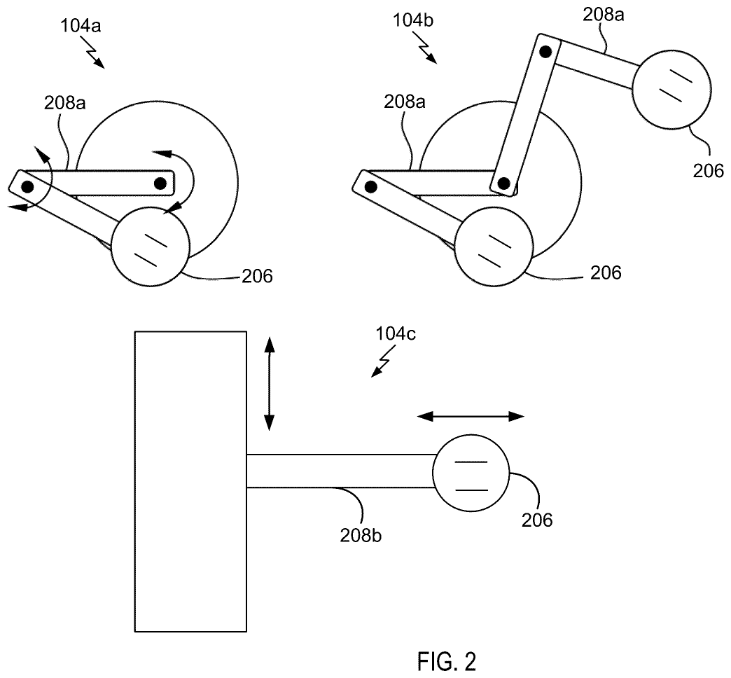

As discussed in further detail below with respect to FIG. 2, the substrate positioning apparatus 104 may comprise an arm that is configured to adjust the position of a substrate 112. The substrate positioning apparatus 104 may be capable of transporting the substrate 112 to and from the one or more chambers 108, as well as adjusting the position of the substrate 112 inside the chambers 108. For example, to adjust the position of a substrate 112 inside a chamber 108, the substrate positioning apparatus 104 may remove the substrate 112 from the chamber 108, and then place the substrate 112 back inside the chamber 108 at an adjusted position.

According to certain embodiments, an equipment front-end module 102 contains or is coupled to one or more computing devices (e.g., a controller) configured to execute methods recited herein and control the substrate positioning apparatus 104.

Certain embodiments provide that a chamber housing 106 is coupled to one or more chambers 108 for processing substrates 112 (i.e., processing chambers). The substrates 112 may be moved into and out of the chambers 108 or from one chamber 108 to another by the substrate positioning apparatus 104.

In some embodiments, each of the chambers 108 are equipped with one or more measuring devices 110 that measure the position of a substrate 112 inside the chamber 108. The one or more measuring devices 110 may comprise sensors that are configured to measure the location of the substrate 112 relative to the pocket of the chamber 108. As an example, a measuring device 110 may comprise a set of sensors that measure the position of the substrate 112 by detecting three points along the circumference of the substrate 112. Based on the location of these three points, the measuring device 110 can accurately determine the location of the center of the substrate 112. In such an example, the sensors may be optical sensors which capture an image. An algorithm stored in a controller determines distances and/or positions based off of the captured image. The center of the pocket of the chamber 108 may be known, or may be determined by similar techniques. The above mentioned technique for determining the location of the substrate 112 relative to the pocket of the chamber 108 is included as an illustrative example, but other techniques for determining the location of the substrate 112 may be used.

Certain embodiments provide that the measuring devices 110 may be calibrated by using a placeholder substrate that contains a sensor at the center of the placeholder substrate. If a measuring device 110 determines a location of the center of the placeholder substrate that is not identical to the location indicated by the sensor in the center of the placeholder substrate, then the measurement device 110 may be adjusted or recalibrated. In addition to sensors, it is contemplated that pattern or image may be specified on the placeholder substrate.

### Example Positioning Apparatuses for Adjusting the Position of a Substrate

FIG. 2 illustrates example positioning apparatuses 104, according to certain embodiments. In some embodiments, the positioning apparatus may be a rotational arm positioning apparatus 104a. The rotational arm positioning apparatus 104a may include a rotational arm 208a comprising a first arm that connects to a base at a point and a second arm that connects to the first arm at an opposite point on the first arm. The rotational arm positioning apparatus 104a may move a substrate by extending and/or rotating. According to some embodiments, the rotational arm positioning apparatus 104a may rotate at specified increments (e.g., at an increment of 0.01 degrees) and extend at specified increments (e.g., at an increment of 0.1 millimeters). In certain embodiments, a rotational arm positioning apparatus with multiple arms 104b may be used. This allows for adjusting the position of multiple substrates simultaneously.

In some embodiments, the positioning apparatus may be an X/Y axis positioning apparatus 104c. The X/Y axis positioning apparatus 104c may include a translational arm 208b that moves substrates by extending and contracting along one axis and/or sliding along another axis. According to some embodiments, X/Y axis positioning apparatus 104c may move at specified increments (e.g., at an increment of 0.1 millimeters). In some embodiments, the X/Y axis positioning apparatus 104c may move a substrate diagonally or along other axes.

Certain embodiments, which may be combined with other embodiments, provide that the positioning apparatus 104 comprises a holder 206 for holding substrates. The holder 206 may, for example, comprise one or more blades that can pick up and/or push the substrate in various directions. The positioning apparatus 104 may be calibrated with respect to the center of a pocket of the chamber so that the holder 206 is aligned with the pocket and that subsequently placed substrates will be placed in the center of the pocket.

In certain embodiments, the positioning apparatus 104 may be calibrated by placing a substrate on a measurement surface. A measurement surface is generally a surface external to the processing chamber, and in one example, may be a substrate support within a transfer chamber. The measurement surface is configured to hold a substrate without causing the substrate to slide and measure the position of the substrate. For example, the measurement surface may be a substrate support (or substrate support pins) within the transfer chamber. In this example, the positioning apparatus 104 may lift the substrate from the pins to a given height, and then place the substrate back on the pins. Because the measurement surface is configured to prevent the substrate from sliding upon placement, a variance between the expected position of the substrate (based on movements by the positioning apparatus 104) and the measured (actual) position of the substrate when placed upon the measurement surface indicates that the positioning apparatus 104 needs to be recalibrated. The variance between the measured position of the substrate on the measurement surface and the expected position of the substrate based on the movement by the positioning apparatus 104 is calculated. If the variance exceeds a threshold, this indicates that the positioning apparatus 104 needs adjustment because the positioning apparatus 104 lacks precision for positioning the substrate. The positioning apparatus 104 may be adjusted in response to this indication so that the measured position of the substrate and the expected position are within the threshold of variance. In some embodiments, the threshold for the variance is approximately +/−one hundred microns. Some embodiments provide that the variance may be calculated based on lifting the substrate from pins used to hold the substrate inside the transfer chamber. The variance may be determined by comparing the original position of the pins relative to the substrate, to the position of the pins relative to the substrate after placement.

### Example Views of Substrates Inside Chambers

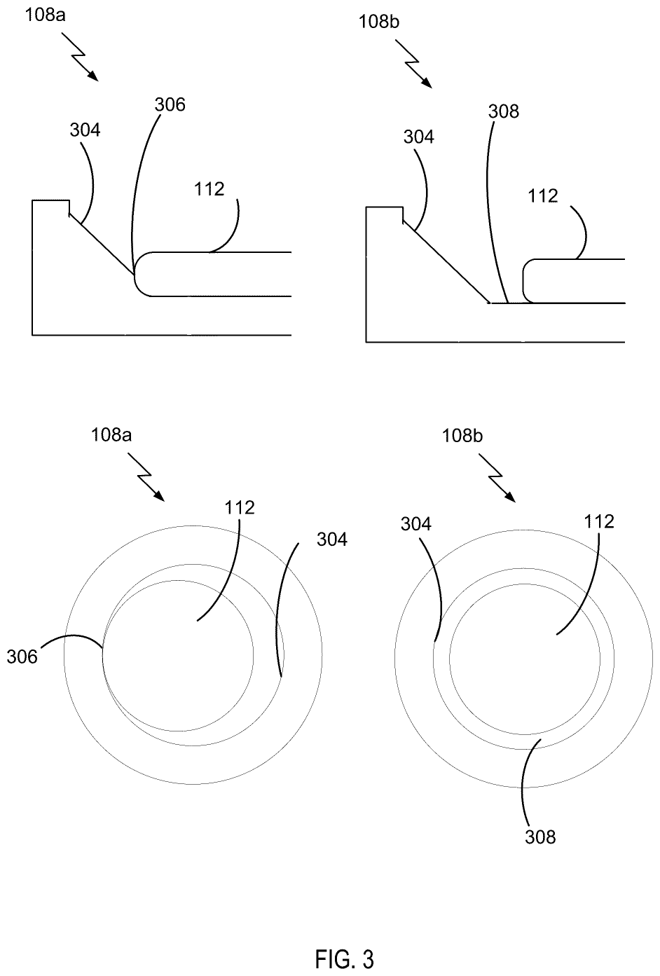

FIG. 3 illustrates example views of substrates 112 inside chambers 108, according to certain embodiments. Chambers 108 generally comprise pockets for holding substrates 112. The substrates 112 may be processed by being heated inside the chambers 108. The chambers 108 are large enough that the substrates 112 may be located close to the edge of a pocket 304 (or a chamber wall) without touching the edge of the pocket 304, leaving an optimal gap between the substrate 112 and the edge of the pocket 304. Sometimes the substrate 112 may touch an edge of the pocket 304 because of incorrect placement or a shift during processing.

In some cases, the edge of the edge of the pocket 304 may be angled in such a way that when the substrate 112 hits the edge of the pocket 304, the substrate 112 slides in an unpredictable manner. For example, if a substrate 112 is placed in a chamber 108 too close to an edge of the pocket 304, the substrate 112 may slide in a direction opposite the edge of the pocket 304. By precisely moving the substrate 112 in small increments, this problem can be avoided.

In some embodiments, it may be determined that a substrate 112 hits an edge of a pocket 304, as shown in state 108a, by analyzing the variance between the measured position of the substrate 112 and the expected position of the substrate 112 based on movements by the positioning apparatus. Measured position may be calculated by using the measurement devices to determine the true location of the substrate 112 within the chamber 108, as discussed above with respect to FIG. 1. Expected position may be calculated according to movements by the positioning apparatus. For example, if the positioning apparatus is configured to place the substrate 112 at a certain position, that position is the expected position. A variance between the expected position and the actual position (e.g., beyond a threshold) indicates a collision 306 between the substrate 112 and the edge of the pocket 304. A collision 306 may occur when the positioning apparatus pushes the substrate 112 against an edge of the pocket 304, which may cause the substrate 112 to slide in a direction or remain in the same location. For example, if the positioning apparatus is configured to move a substrate 0.2 millimeters upward in a chamber 108 and the substrate 112 is already touching the upward wall of the chamber 108 or the pocket, there may be a variance of 0.2 millimeters between the expected position and the measured position since the substrate 112 is unable to move further in that direction. The variance may be greater than 0.2 millimeters in this case if sliding occurs.

According to certain embodiments, the expected position may be updated after each placement of a substrate. For example, the positioning apparatus may be configured to place a substrate 112 in a certain location. The measurement devices may indicate that the substrate 112 was placed in another location. Based on this indication, the positioning apparatus will determine that the substrate 112 is in the other location instead of in the certain location and recognize the other location as the true location of the substrate 112. This updating process prevents growth in error of the expected position as the position is adjusted.

Certain embodiments provide that once the variance between expected and measured position reaches a threshold (e.g., two hundred microns, or another threshold) in response to the substrate 112 being moved, it is determined that an edge of the pocket 304 has been hit. Once this determination is made, a limit is set for that direction of movement. Some embodiments provide that the substrate 112 is then moved in the opposite direction. After multiple incremental movements in the opposite direction, the variance between expected and measured position of the substrate 112 may increase again. Once the variance between expected and measured position reaches a threshold in response to the substrate 112 being moved in the opposite direction, it is determined that an edge opposite to the first edge of the pocket 304 has been hit. The positioning apparatus may then be configured to position the substrate 112 in the center of a line extending from the first edge to the second edge. For example, the positioning apparatus may incrementally (e.g., each increment may be 0.01 millimeters, as discussed above, or another increment) move the substrate 112 forward by set increments along the Y axis. After, for example, seven increments the variance between expected and measured position may reach a threshold. Then the positioning apparatus may incrementally move the substrate 112 backward along the Y axis. As the substrate 112 is being moved backward, the variance may increase once again when the substrate 112 hits the opposite edge after, for example, fifteen increments. Based on this example, the variance reaching the threshold indicates that the center of the Y axis is eight increments forward from the position where the substrate 112 hit the opposite edge (e.g., moving the substrate 112 eight increments forward results in the center of the substrate 112 being located at the midpoint of a line that is fifteen increments long). The substrate 112 may be moved forward eight increments along the Y axis to the center of the Y axis, and this configuration for the positioning apparatus may be saved as the center of the Y axis. Because the configuration is saved, the substrate 112 may be moved back to this location along the Y axis even if there is a shift during processing.

According to certain embodiments, after a first set of edges have been hit and a corresponding center point along a line between the edges has been determined, a center point for a different line may be determined by repeating the process described above with a different direction and opposite direction. In some embodiments, the second direction and second opposite direction may form an axis that is perpendicular to an axis formed by the first direction and first opposite direction. For example, the substrate 112 may be moved forward along the X axis until an edge of the pocket 304 is found, and then backward along the X axis until an opposite edge is found. The positioning apparatus may be configured to position the substrate 112 in the center of the X axis based on these determined edges. When the positioning apparatus is configured to position the substrate 112 in the center of multiple axes, such as perpendicular axes X and Y, the substrate 112 may be placed in the center of the pocket, as shown in 108b. While detecting a set of edges for axes that are perpendicular to one another is included as an example, it is noted that the angles between axes for which edges are detected may be other than ninety degrees. For example, edges may be detected along multiple axes with sixty degrees of separation (or another number of degrees) between each axis. Each of the axes may intersect at the center of the pocket. When the substrate 112 is located in the center of the pocket, an optimal gap 308 between the substrate 112 and the pocket may be formed.

In certain embodiments, the substrate 112 may be initially placed in a way that causes the substrate 112 to hit an edge of the pocket 304. This may be caused by a lack of precision of the positioning apparatus, as discussed above with respect to FIG. 2. Also, lack of proper calibration of the positioning apparatus with respect to the chamber 108 can cause the substrate 112 to hit the edge of the pocket 304 on initial placement. Improper air pressure within the chamber 108 can also cause the substrate 112 to hit the edge of the pocket 304 on initial placement. The positioning apparatus may be calibrated and/or the air pressure within the chamber 108 may be adjusted in response to a substrate 112 hitting the edge of the pocket 304 during initial placement.

According to some embodiments, the substrate 112 may be adjusted in one direction, and a variance corresponding to a different direction may be used to determine that the substrate 112 has hit an edge of the pocket 304. For example, a substrate 112 may be moved along the X axis. As a result of this movement, the substrate 112 may hit an edge of the pocket 304 and slide in a different direction due to the angle of the edge of the pocket 304, as discussed above. This sliding may result in a variance between an expected position along the Y axis and the measured position along the Y axis. This variance can be used to determine that the substrate hit the edge of the pocket 304 along the X axis, since the adjustment that caused the variance was made with respect to the X axis.

In some embodiments, a determination that an edge has been reached in a given direction along a given axis is not made until the variance between the expected position and the detected position of the substrate exceeds a threshold for a given number of successive incremental adjustments to the position of the substrate in the given direction along the given axis. In such cases, the edge may be determined to be associated with the first incremental adjustment that caused the variance between the expected position and the detected position of the substrate to exceed the threshold. For example, if the 7^{th}, 8^{th}, and 9^{th} consecutive incremental adjustments result in the variance between the expected position and the detected position of the substrate exceeding the threshold, and the system is configured to detect an edge when 3 consecutive adjustments result in the variance between the expected position and the detected position of the substrate exceeding the threshold, then the 7^{th} incremental adjustment may be determined to be the adjustment that is associated with detecting the edge, as the 7^{th} incremental adjustment is the first of the 3 for which the variance between the expected position and the detected position of the substrate exceeded the threshold.

Such an embodiment may provide a greater amount of certainty that an edge has been reached, such as accounting for anomalous instances of variance exceeding a threshold when an edge has not in fact been reached.

### Example Operations for Automatically Positioning a Substrate Inside a Chamber

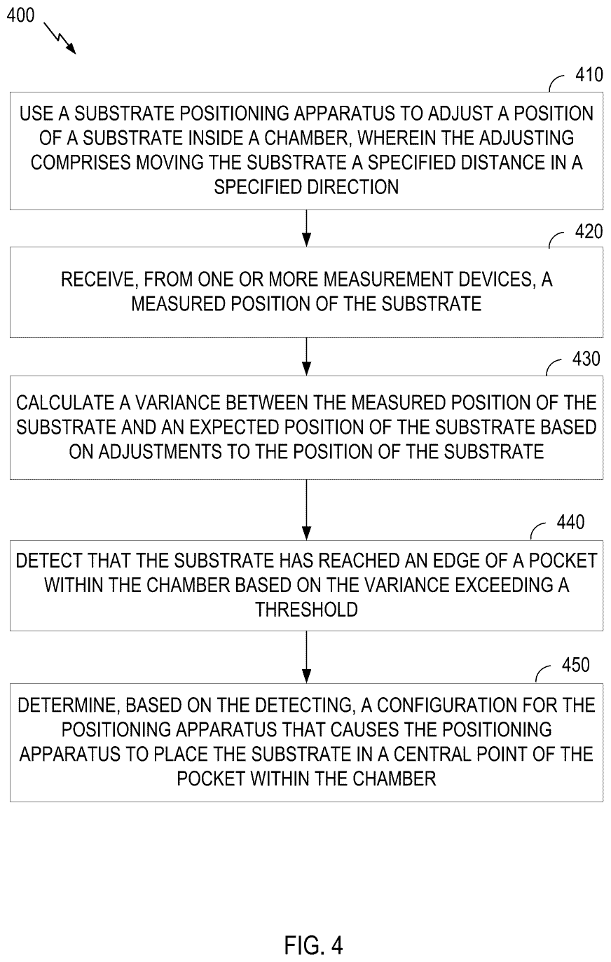

FIG. 4 is a flow diagram of example operations 400 for automatically positioning a substrate inside a chamber. Operations 400 may be performed by a computing device, such as the computing device as discussed with respect to FIG. 1.

Operations 400 begin at 410, where a substrate positioning apparatus is used to adjust a position of a substrate inside a chamber by moving the substrate a specified distance in a specified direction. In some embodiments, using the substrate positioning apparatus to adjust the position of the substrate further comprises incrementally adjusting the position of the substrate. Some embodiments provide that the positioning apparatus retrieves the substrate from a location other than the chamber and places the substrate inside the chamber. According to some embodiments, the positioning apparatus is calibrated based on placing the substrate on a measurement surface and calculating a variance between a given measured position of the substrate and a corresponding expected position of the substrate. Certain embodiments provide that the positioning apparatus is calibrated based on placing the substrate on a measurement surface and calculating a variance between a given measured position of the substrate and a corresponding expected position of the substrate. In some embodiments, the positioning apparatus is calibrated based on the central point of the chamber.

Operations 400 continue at 420, with receiving, from one or more measurement devices, a measured position of the substrate. According to certain embodiments, the measured position of the substrate is determined based on at least three points along the circumference of the substrate. In some embodiments, the one or more measurement devices are calibrated using a placeholder substrate that contains a measurement sensor.

Operations 400 continue at 430, with calculating a variance between the measured position of the substrate and an expected position of the substrate based on adjustments to the position of the substrate.

Operations 400 continue at 440, with detecting that the substrate has reached an edge of a pocket within the chamber based on the variance exceeding a threshold. In some embodiments, the substrate is adjusted in one direction, and a variance corresponding to a different direction is used to determine that the substrate has reached an edge of the pocket corresponding to the one direction. Certain embodiments provide that the detecting that the substrate has reached the edge of the pocket is further based on one or more previous variances determined from one or more previous positional adjustments by the substrate positioning apparatus of the substrate inside the chamber. According to some embodiments, the detecting that the substrate has reached the edge of the pocket is further based on determining that the variance and the one or more previous variances exceed a threshold.

Operations 400 continue at 450, with determining, based on the detecting, a configuration for the positioning apparatus that causes the positioning apparatus to place the substrate in a central point of the pocket within the chamber.

In certain embodiments, the positioning apparatus comprises an arm that is configured to move the substrate by extending and rotating. Some embodiments provide that the positioning apparatus comprises an arm that adjusts the position of the substrate along a first axis and a second axis that is perpendicular to the first axis.

While the foregoing is directed to embodiments of the present disclosure, other and further embodiments of the disclosure may be devised without departing from the basic scope thereof, and the scope thereof is determined by the claims that follow.

What is claimed is:

1. A method for positioning a substrate inside a chamber, comprising:
using a substrate positioning apparatus to adjust a position of a substrate inside a chamber, wherein the adjusting comprises moving the substrate a specified distance in a specified direction;
receiving, from one or more measurement devices, a measured position of the substrate;
calculating a variance between the measured position of the substrate and an expected position of the substrate based on adjustments to the position of the substrate;
detecting that the substrate has reached an edge of a pocket within the chamber based on the variance exceeding a threshold; and
determining, based on the detecting, a configuration for the positioning apparatus that causes the positioning apparatus to place the substrate in a central point of the pocket within the chamber.

2. The method of claim 1, wherein using the substrate positioning apparatus to adjust the position of the substrate further comprises incrementally adjusting the position of the substrate.

3. The method of claim 1, wherein the measured position of the substrate is determined based on at least three points along a circumference of the substrate.

4. The method of claim 1, wherein the positioning apparatus retrieves the substrate from a location other than the chamber and places it inside the chamber.

5. The method of claim 4, wherein the positioning apparatus is calibrated based on placing the substrate on a measurement surface and calculating a variance between a given measured position of the substrate and a corresponding expected position of the substrate.

6. The method of claim 1, wherein the positioning apparatus is calibrated based on the central point of the pocket.

7. The method of claim 1, wherein the one or more measurement devices are calibrated using a placeholder substrate that contains a measurement sensor.

8. The method of claim 1, wherein the positioning apparatus comprises an arm that adjusts the position of the substrate along a first axis and a second axis that is perpendicular to the first axis.

9. The method of claim 1, wherein the positioning apparatus comprises an arm that is configured to move the substrate by extending and rotating.

10. The method of claim 1, wherein the substrate is adjusted in one direction, and a variance corresponding to a different direction is used to determine that the substrate has reached an edge of the pocket corresponding to the one direction.

11. The method of claim 1, wherein the detecting that the substrate has reached the edge of the pocket is further based on one or more previous variances determined from one or more previous positional adjustments by the substrate positioning apparatus of the substrate inside the pocket.

12. The method of claim 11, wherein the detecting that the substrate has reached the edge of the pocket is further based on determining that the variance and the one or more previous variances exceed a threshold.

13. A method for positioning a substrate inside a chamber, comprising:
using a substrate positioning apparatus to adjust a position of a substrate inside a chamber, wherein the adjusting comprises moving the substrate a specified distance in a specified direction;
receiving, from one or more measurement devices, a first measured position of the substrate;
calculating a first variance between the first measured position of the substrate and a first expected position of the substrate, wherein the first expected position is based on adjustments to the position of the substrate;
detecting that the substrate has reached a first edge of a pocket within the chamber based on the first variance exceeding a threshold;
using the substrate positioning apparatus to move the substrate a specified distance in a direction that is opposite to the specified direction;
receiving, from the one or more measurement devices, a second measured position of the substrate;
calculating a second variance between the second measured position of the substrate and a second expected position of the substrate, wherein the second expected position is based on the first measured position of the substrate and adjustments to the position of the substrate;
detecting that the substrate has reached a second edge of the pocket based on the second variance exceeding a threshold; and
determining a configuration for the positioning apparatus by selecting a given configuration for the positioning apparatus that is intermediate to a first configuration of the positioning apparatus that caused the substrate to reach the first edge and a second configuration of the positioning apparatus that caused the substrate to reach the second edge.

14. A substrate processing device, comprising:
a processing chamber for receiving a substrate;
one or more measurement devices for measuring a position of the substrate;
a substrate positioning apparatus that is capable of adjusting the position of the substrate; and
a computing device capable of:
receiving data from the one or more measurement devices;
determining, based on the data received from the measurement devices, the position of the substrate;
determining, based on adjustments to the position of the substrate, an expected position of the substrate;
calculating a variance between the position of the substrate determined from the data received from the measurement devices and the expected position of the substrate; and
determining a configuration for the positioning apparatus based on the calculated variance.

15. The substrate processing device of claim 14, wherein the one or more measurement devices detect at least three points along a circumference of the substrate.

16. The substrate processing device of claim 14, wherein the positioning apparatus comprises an arm that adjusts the position of the substrate along a first axis and a second axis that is perpendicular to the first axis.

17. The substrate processing device of claim 14, wherein the positioning apparatus comprises an arm that is configured to move the substrate by extending and rotating.

18. The substrate processing device of claim 14, wherein the positioning apparatus is configured to retrieve the substrate from a location other than the chamber and places it inside the chamber.

19. The substrate processing device of claim 18, further comprising a measurement surface, wherein the positioning apparatus is calibrated based on placing the substrate on the measurement surface and calculating a variance between a measured position of the substrate and an expected position of the substrate.

20. The substrate processing device of claim 14, wherein the positioning apparatus is calibrated based on a central point of a pocket within the chamber.
